(19) United States
(12) Patent Application Publication
(10) Pub. No.: US 2007/0119849 A1
(43) Pub. Date: May 31, 2007

(54) Heater and vapor deposition source having the same

(76) Inventors: Min Jae Jeong, Yongin (KR); Do Geun Kim, Changwon (KR); Young Mook Choi, Yongin (KR)

Correspondence Address: CHRISTIE, PARKER & HALE, LLP, PO BOX 7068, PASADENA, CA, 91109-7068, US

(21) Appl. No.: 11/514,313

(22) Filed: Aug. 30, 2006

(30) Foreign Application Priority Data
Aug. 30, 2005 (KR) 10-2005-0080280

(51) Int. Cl. H05B 3/02; C23C 16/00

(52) U.S. Cl. 219/546; 118/724

(57) ABSTRACT

A heater and a vapor deposition source having the same capable of plating materials having a uniform thickness on a board by ensuring a temperature uniformity of a melting pot. The heater is provided on at least one of an upper side or a lower side of the melting pot to heat the melting pot. The heater includes a plurality of bents with non-uniform pitches. A central part of the heater has a pitch larger than pitches at both edge parts of the heater. As such, the plurality of bents with the non-uniform pitches reduce a temperature difference between the central part and the edge parts of the heater, and makes an evaporation of plating materials uniform, thereby making the thickness of plated materials uniform.

### CROSS-REFERENCE TO RELATED APPLICATION

This application claims priority to and the benefit of Korean Patent Application No. 10-2005-0080280, filed on Aug. 30, 2005, in the Korean Intellectual Property Office, the entire content of which is incorporated herein by reference.

### BACKGROUND

1. Field of the Invention

The present invention relates to a heater and a vapor deposition source having the same, and, more particularly, to a heater and a vapor deposition source capable of plating materials having a uniform thickness on a board by ensuring a temperature uniformity of a melting pot.

2. Discussion of Related Art

There are several ways to form thin films on a board including physical vapor deposition (PVD) (e.g., evaporation, ion-plating, and sputtering), and chemical vapor deposition (CVD) by gas reaction.

Generally, in many fields including semiconductor elements, organic light emitting diodes (OLED), etc., thin films are formed by a vacuum plating method using evaporation. In the vacuum plating method using evaporation, an indirect (or inductive) heating-type evaporation source can be used.

The indirect heating-type evaporation source heats plating materials provided in a melting pot to a set temperature to evaporate the plating materials. The indirect heating-type evaporation source includes a heater to heat the melting pot and a nozzle part to spray the plating materials discharged from the heated melting pot to a board.

However, it is more difficult to use the indirect heating type plating method to plate large-size materials, as compared with a sputtering deposition method. Therefore, in order to plate large-size materials using the indirect heating type plating method, various evaporation sources arranged in a row are used, or linear-type evaporation sources are used.

FIG. 1 schematically illustrates an example of using existing linear-type evaporations, and FIG. 2 illustrates a rectangular parallelepiped-type melting pot 120. In FIG. 1, an evaporation source 100 includes a rectangular parallelepiped-type housing 110, the melting pot 120 installed inside the housing 110, a heater (not shown) to heat the melting pot 120, an insulation part covering the heater, and a nozzle part including a spray nozzle 140 to spray plating materials to the outside. In FIG. 2, the spray nozzle 140 is shown to be connected with the melting pot 120.

In FIG. 1, a first heat blocking plate 180 for blocking the heat of the plating materials is installed at an end part of the spray nozzle 140 for spraying the plating materials evaporated from the melting pot 120, and a second heat blocking plate 190 for preventing the spread of the plating materials and the diffusion of the radiant heat to an outer part of the housing 110 is installed at upper and lower parts of the first heat blocking plate 180.

Also, a thickness meter 142 for measuring the thickness of the plating of the plating materials sprayed through the spray nozzle 140 is installed at one side of the evaporation source 100.

The melting pot 120 is formed as a rectangular parallelepiped type melting pot having an optimal containing space. In FIG. 1, the melting pot 120 is built in the housing 100. In one embodiment, the spray nozzle 140 is arranged with the melting pot at random intervals in order to ensure a uniformity of materials on the board.

The melting pot 120 accepts the plating materials, and the heater is arranged near the melting pot 120 in order to heat the melting pot. Depending on what is needed, the heater can be installed at both upper and lower sides of the melting pot 120, or can be installed at only one of the upper side or the lower side.

FIG. 3 illustrates an existing heater 130.

Referring to FIG. 3, the heater 130 is used to heat the rectangular parallelepiped-type melting pot 120. The heater 130 has a size that can cover at least one side of the melting pot 120 having a fixed height and a fixed length. In addition, the heater 130 can be manufactured to contain the melting pot 120 in it.

Also, in order to provide electricity to the heater 130, an electric wire is made to contact the heater 130, and a power supply part for supplying power to the electric wire is arranged. In one embodiment, a case (not shown) is installed to cover the outer side of the power supply part in order to safely supply power to the heater 130. As shown in FIG. 3, the existing heater 130 is bent to have a designated pitch at regular intervals such that the form of the heater 130 can generate an optimal amount of heat for a given area, considering thermal conduction and resistance.

However, in the heater 130 bent to have the same pitch at regular intervals, the heat emitted by the heater 130 using power from the outside power source is not uniformly provided to the whole of the melting pot 120 because there is more heat emitted in a central part of the heater 130 than in an edge part of the heater 130. Consequently, there is more evaporation from a central part of the melting pot 120 than from an edge part of the melting pot 120 such that the thickness of the plating materials plated on the board is not uniform.

In other words, because the central part of the melting pot 120 is heated to a higher temperature than left and right edge parts of the melting pot 120, a central part of the plating materials plated on the board is thicker than its edge parts.

### SUMMARY OF THE INVENTION

Accordingly, it is an aspect of the present invention to provide a heater and a vapor deposition source capable of reducing a temperature discrepancy of a central part and edge parts of the heater by uniformly distributing the heating temperature, and/or capable of plating materials having a uniform thickness on a board by ensuring a uniform evaporation of the materials.

An embodiment of the present invention provides a heater provided on at least one of an upper side or a lower side of a melting pot of a depositing device to heat the melting pot. The heater includes a plurality of bents with non-uniform pitches. A central part of the heater has a pitch larger than pitches at both edge parts of the heater.

In one embodiment, a ratio of the pitch of the central part and one of the pitches (b) of the edge parts ranges from about 1.5 to 5. In one embodiment, the heater includes pitch intervals gradually increasing from either one of the edge parts of the heater to the central part of the heater.

Another embodiment of the present invention provides an evaporation source having a housing, a melting pot built in the housing for accommodating deposition materials, a plane-type heater provided on at least one of an upper side or a lower side of the melting pot to heat the melting pot, and a nozzle part including a spray nozzle to spray the deposition materials evaporated from the melting pot. Here, a central part of the heater has a larger pitch than pitches at both edge parts of the heater.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 schematically illustrates an example of existing linear-type evaporations;

FIG. 2 illustrates an existing melting pot;

FIG. 3 illustrates an existing heater;

FIG. 4 illustrates an embodiment of a heater according to the present invention;

FIG. 5 illustrates another embodiment of a heater according the present invention;

FIG. 6 is a graph illustrating the result of a simulation on an existing heater; and

FIG. 7 is a graph illustrating the result of a simulation on an embodiment of a heater according to the present invention.

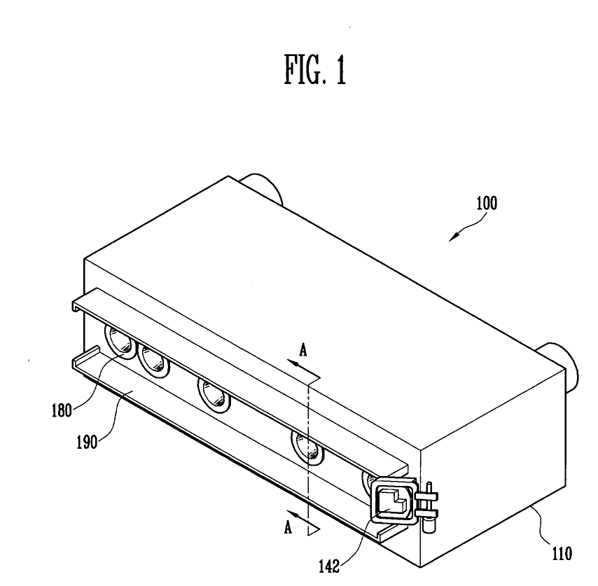

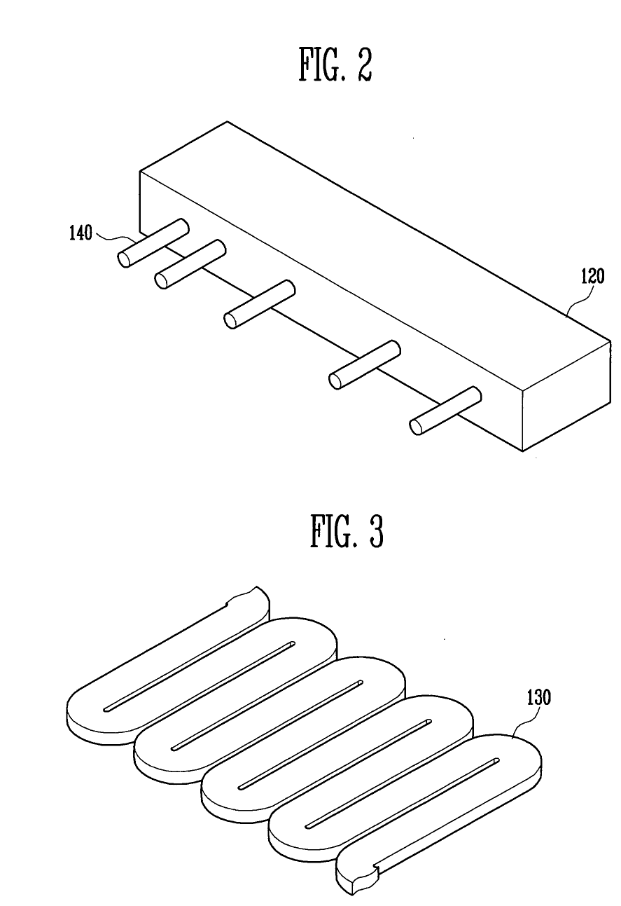

### DETAILED DESCRIPTION

The accompanying drawings, together with the specification, illustrate exemplary embodiments of the present invention, and, together with the description, serve to explain the principles of the present invention.

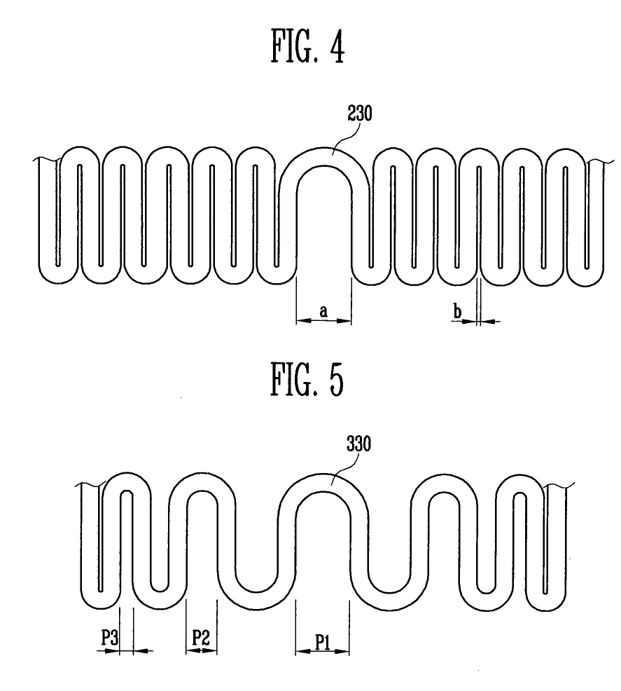

FIG. 4 illustrates an embodiment of a heater 230 according to the present invention. The heater 230 is used to heat a rectangular parallelepiped-type melting pot, and can cover at least one side of the melting pot having certain width, height, and length. Also, depending on the situation, the heater 230 can be installed on the upper side and the lower side of the melting pot, or can be installed on only one of the upper side of the melting pot or the lower side of the melting pot.

The heater 230 is formed as a plane-type heater, and evaporates plating (or charged) materials inside the melting pot with an installed power source part (not shown) for providing electricity to the heater 230.

In other words, only when the amount of heat emitted from the heater 230 is distributed uniformly at the whole heater 230 is the heat uniformly transmitted to the plating materials in the melting pot; then the evaporation is done uniformly, and as a result, the plating materials are uniformly plated on the board.

However, in a linear-type heater, the temperature of the central part of the heater is higher than that of the edge parts of the heater primarily because the heat dissipates out from the electrode parts connected to both edge parts of the heater, and this temperature difference becomes bigger as the overall temperature of the heater goes up.

As such, to ensure the uniformity of the temperature throughout the heater, it is necessary to increase the amount of the emitted heat at both edge parts of the linear-type heater. That is, by raising the temperature of both edge parts of the heater, a certain uniformity can be acquired.

Therefore, referring to FIG. 4, by using irregular pitch intervals, the heater 230 in an embodiment of the present invention ensures the uniformity of the temperature by allowing for more heat to be emitted at both edge parts of the heater 230.

In other words, the heater 230 forms a wider pitch (a) at a central part of the heater 230 by omitting at least a bent at the central part, and forms narrower pitches (b) at both edge parts of the heater 230.

Here, the ratio (a/b) of the pitch (a) at the central part and one of the pitches (b) of the edge parts can range from 1.5 to 5 in one embodiment of the present invention. Also, depending on the materials and characteristics of the heater 230 used, the ratio (a/b) can be changed within the range from 1.5 to 5.

Also, according to an embodiment of the present invention, only one pitch (a) is formed at the central part, but a heater according to an embodiment of the present invention can be formed to have multiple pitches (a) at its central part.

In view of the foregoing, the heater 230 of FIG. 4 can ensure an uniformity of the temperature of the melting pot and ensure a uniform thickness of plated materials by regulating the area of emitted heat of the heater 230.

FIG. 5 illustrates another embodiment of a heater 330 according to the present invention. In FIG. 5, the heater 330 is shown to have pitch intervals that become gradually wider toward a central direction of the heater 330 from edge parts of the heater 330.

In other words, from both edge parts of the heater 330 to a central part of the heater 330, the pitch intervals are gradually widened with the order of (P₁)>(P₂)>(P₃), so the pitch (P₁) at the central part is the widest, and the pitches (P₃) at the edge parts are the narrowest.

The heater 330 of FIG. 5 can also ensure an uniformity of the temperature of a melting pot and ensure a thickness of plated materials by regulating the area of emitted heat of the heater 330.

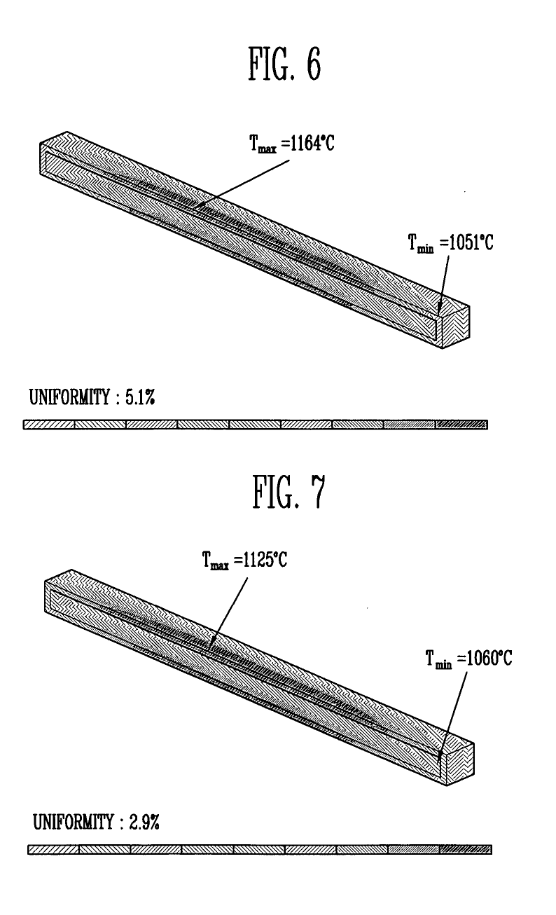

FIG. 6 is a graph illustrating the result of a simulation on an existing heater and FIG. 7 is a graph illustrating the result of a simulation on a heater according to an embodiment of the present invention. As shown in FIGS. 6 and 7, in the case of the existing heater having same pitches (e.g., the heater 130), the maximum temperature (Tₘₐₓ) of a melting pot is 1164° C., and the minimum temperature (Tₘᵢₙ) is 1051° C., making a temperature difference of 113° C. and an uniformity of 5.1%. By contrast, in the case of the embodiment of the present invention having wider pitches at the central part than pitches at the edge parts (e.g., the heater 230 or 330), the maximum temperature (Tₘₐₓ) of a melting pot is 1125° C., and the minimum temperature (Tₘᵢₙ) is 1060° C., making a temperature difference of 65° C. and an uniformity of 2.9%.

In this way, the heater (e.g., the heater 230 or 330) of the embodiments of the present invention reduces the maximum and minimum temperature difference of the melting pot to about one half (½), as compared with the existing heater (e.g., the heater 130), and the uniformity improves to 2.9%.

Therefore, because a heater of the present invention significantly improves the temperature uniformity of a melting pot, the evaporation of plating materials becomes uniform, making the thickness of plated materials uniform, thereby improving device yield and productivity.

While the invention has been described in connection with certain exemplary embodiments, it is to be understood by those skilled in the art that the invention is not limited to the disclosed embodiments, but, on the contrary, is intended to cover various modifications included within the spirit and scope of the appended claims and equivalents thereof.

What is claimed is:

1. A heater provided on at least one of an upper side or a lower side of a melting pot of a depositing device to heat the melting pot, the heater comprising:
a plurality of bents with non-uniform pitches,
wherein a central part of the heater has a pitch larger than pitches at both edge parts of the heater.

2. The heater as claimed in claim 1, wherein a ratio of the pitch of the central part and one of the pitches of the edge parts ranges from about 1.5 to 5.

3. The heater as claimed in claim 1, wherein the heater comprises pitch intervals gradually increasing from either one of the edge parts of the heater to the central part of the heater.

4. A vapor deposition source comprising:
a housing;
a melting pot built in the housing for accommodating deposition materials;
a plane-type heater provided on at least one of an upper side or a lower side of the melting pot to heat the melting pot, wherein a central part of the heater has a larger pitch than pitches at both edge parts of the heater; and
a nozzle part including a spray nozzle to spray the deposition materials evaporated from the melting pot.

5. The vapor deposition source as claimed in claim 4, wherein a ratio of the pitch of the central part and one of the pitches of the edge parts ranges from about 1.5 to 5.

6. The vapor deposition source as claimed in claim 4, wherein the heater is formed so that pitch intervals gradually increase from the edges of the heater to the central part of the heater.

7. A heater for uniformly heating a melting pot of a depositing device, the heater comprising:
a plurality of bents with non-uniform pitches,
wherein a central part of the heater has a pitch larger than pitches at both edge parts of the heater.

8. The heater as claimed in claim 7, wherein the heater is positioned on at least one of an upper side or a lower side of the melting pot to heat the melting pot.

9. The heater as claimed in claim 7, wherein the plurality of bents with the non-uniform pitches are formed by eliminating a bent at the central part of the heater.

10. The heater as claimed in claim 7, wherein a ratio of the pitch of the central part and one of the pitches of the edge parts ranges from about 1.5 to 5.

11. The heater as claimed in claim 7, wherein the heater comprises pitch intervals gradually increasing from either one of the edge parts of the heater to the central part of the heater.
